(19) United States
(12) Patent Application Publication
(10) Pub. No.: US 2026/0144128 A1
(43) Pub. Date: May 21, 2026

(54) SEMICONDUCTOR PACKAGE

(71) Applicant: SAMSUNG ELECTRONICS CO., LTD., Suwon-si (KR)

(72) Inventors: Sanghoon LEE, Suwon-si (KR); Donghwi KIM, Suwon-si (KR); Kyoung Lim SUK, Suwon-si (KR); Jaegun SHIN, Suwon-si (KR); Gwangjae JEON, Suwon-si (KR)

(73) Assignee: SAMSUNG ELECTRONICS CO., LTD., Suwon-si (KR)

(21) Appl. No.: 19/213,750

(22) Filed: May 20, 2025

(30) Foreign Application Priority Data
Nov. 21, 2024 (KR) 10-2024-0167421

(51) Int. Cl. H01L 23/31; H01L 23/48; H01L 25/16

(52) U.S. Cl. CPC H10W 74/121; H10W 20/20; H10W 90/00

(57) ABSTRACT

A semiconductor package may include a base die, a plurality of lower core dies stacked on the base die, an upper core die on the plurality of lower core dies, an oxide structure covering side surfaces of the plurality of lower core dies and a side surface of the upper core die, and a molding structure provided to cover a side surface of the oxide structure and spaced apart from the plurality of lower core dies and the upper core die with the oxide structure interposed therebetween. Each of the base die and the plurality of lower core dies may include a penetration electrode, and the upper core die may include an insulating layer provided on a bottom surface thereof and a pad provided in the insulating layer. The oxide structure may expose an edge portion of a top surface of the base die.

### CROSS-REFERENCE TO RELATED APPLICATIONS

This U.S. non-provisional patent application claims priority under 35 U.S.C. § 119 to Korean Patent Application No. 10-2024-0167421, filed on Nov. 21, 2024, in the Korean Intellectual Property Office, the entire contents of which are hereby incorporated by reference.

### BACKGROUND OF THE INVENTION

The present disclosure relates to a semiconductor package, and in particular, to a semiconductor package including a plurality of stacked semiconductor chips.

The rapid development of the electronics industry has led to an increasing demand for electronic devices with higher performance. In order to achieve higher performance, there is a growing demand for methods of arranging a plurality of semiconductor chips. In order to satisfy this demand, a semiconductor package technology has been proposed in which a plurality of vertically stacked semiconductor chips are connected using through-substrate vias (TSVs).

### SUMMARY

An embodiment of the inventive concept provides a semiconductor package with improved structural stability.

According to an embodiment of the inventive concept, a semiconductor package may include a base die, a plurality of lower core dies stacked on the base die, an upper core die on the plurality of lower core dies, an oxide structure covering side surfaces of the plurality of lower core dies and a side surface of the upper core die, and a molding structure provided to cover a side surface of the oxide structure and spaced apart from the plurality of lower core dies and the upper core die with the oxide structure interposed therebetween. Each of the base die and the plurality of lower core dies may include a penetration electrode, and the upper core die may include an insulating layer provided on a bottom surface thereof and a pad provided in the insulating layer. The oxide structure may expose an edge portion of a top surface of the base die.

According to an embodiment of the inventive concept, a semiconductor package may include a base die, a plurality of lower core dies stacked on the base die, an upper core die on the plurality of lower core dies, an oxide structure covering side surfaces of the plurality of lower core dies and a side surface of the upper core die, and a molding structure on a side surface of the oxide structure. A width of the oxide structure in a horizontal direction may be constant regardless of a level, and a level of a top surface of the upper core die may be substantially equal to a level of a top surface of the oxide structure.

According to an embodiment of the inventive concept, a semiconductor package may include a package substrate, an interposer substrate on the package substrate, a logic chip on the interposer substrate, and a plurality of chip stacks, which are spaced apart from each other in a first direction parallel to a top surface of the package substrate, with the logic chip interposed therebetween. One of the plurality of chip stacks may include a base die, a plurality of lower core dies stacked on the base die, an upper core die on the plurality of lower core dies, an oxide structure covering side surfaces of the plurality of lower core dies and a side surface of the upper core die, and a molding structure covering a side surface of the oxide structure. A width of the oxide structure on the upper core die in the first direction may be substantially equal to a width of the oxide structure on one of the plurality of lower core dies in the first direction.

### BRIEF DESCRIPTION OF THE DRAWINGS

FIG. 1 is a sectional view illustrating a semiconductor package according to an embodiment of the inventive concept.

FIG. 2 is a sectional view illustrating a semiconductor package according to an embodiment of the inventive concept.

FIGS. 3, 4, 5, 6, 7, 8, 9, 10, 11, 12, 13, 14, 15, and 16 are sectional views illustrating a process of fabricating a semiconductor package, according to an embodiment of the inventive concept.

FIG. 17 is a sectional view illustrating a portion of a process of fabricating a semiconductor package, according to an embodiment of the inventive concept.

FIG. 18 is a plan view illustrating a semiconductor package according to an embodiment of the inventive concept.

FIG. 19 is a sectional view taken along a line A-A′ of FIG. 18.

### DETAILED DESCRIPTION

Example embodiments of the inventive concepts will now be described more fully with reference to the accompanying drawings, in which example embodiments are shown.

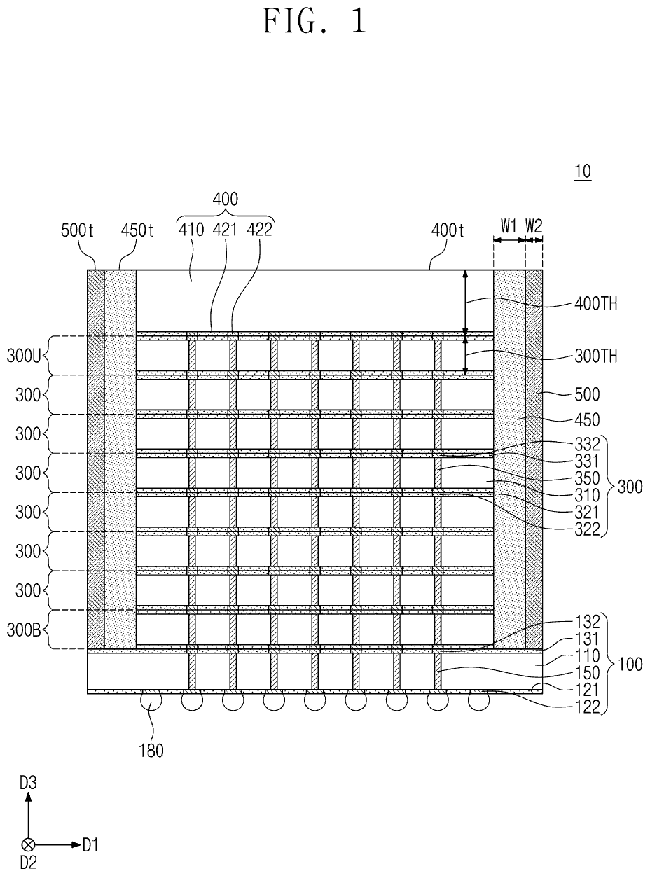

FIG. 1 is a sectional view illustrating a semiconductor package according to an embodiment of the inventive concept.

Referring to FIG. 1, a semiconductor package 10 may be, for example, a high-bandwidth memory (HBM). In the present specification, the semiconductor package 10 may be referred to as a chip stack 10.

The semiconductor package 10 may include a base die 100, a plurality of lower core dies 300, an upper core die 400, an oxide structure 450, and a molding structure 500.

The base die 100 may be provided in a lower portion of the semiconductor package 10. In the present specification, the base die 100 may be referred to as a logic die, a logic chip, a base chip, a buffer chip, a buffer die, or a memory controller. The base die 100 may be used as a logic chip increasing data transmission efficiency and reducing power consumption.

In the present specification, a first direction D1 may be defined as a direction that is parallel to a top surface of the base die 100. A second direction D2 may be defined as a direction that is parallel to the top surface of the base die 100 and is perpendicular to the first direction D1. A third direction D3 may be defined as a direction perpendicular to the top surface of the base die 100.

The base die 100 may include a first semiconductor substrate 110, a first upper insulating layer 131, a first upper pad 132, a first penetration electrode 150, a first lower insulating layer 121, and a first lower pad 122.

The first semiconductor substrate 110 may be formed of or include a semiconductor material (e.g., silicon or germanium). The first penetration electrodes 150 may be provided to penetrate the first semiconductor substrate 110. The first penetration electrodes 150 may be spaced apart from each other in the first direction D1. The first penetration electrode 150 may be formed of or include a conductive material (e.g., copper). A diffusion prevention pattern (e.g., tantalum nitride (TaN), tantalum (Ta), titanium nitride (TiN), or tungsten (W)) may be disposed between the first penetration electrode 150 and the first semiconductor substrate 110.

The first lower insulating layer 121 may be disposed on a bottom surface of the first semiconductor substrate 110. Although not shown, an interconnection pattern and a circuit layer may be provided in the first lower insulating layer 121. The first lower pads 122 may be provided in the first lower insulating layer 121.

The first upper insulating layer 131 may be disposed on a top surface of the first semiconductor substrate 110. The first upper pads 132 may be provided in the first upper insulating layer 131. The first lower insulating layer 121 and the first upper insulating layer 131 may be formed of or include at least one of silicon oxide (SiO₂), silicon nitride (Si₃N₄), or silicon oxynitride (SiOₓN_{y}).

First connection terminals 180 may be provided on the first lower pads 122, respectively. The first connection terminals 180 may include solder balls or solder bumps. The first connection terminals 180 may be formed of or include at least one of silver, copper, tin, or alloys thereof.

The lower core dies 300 may be disposed on the base die 100. Each of the lower core dies 300 may be a memory chip. As an example, the lower core dies 300 may be one of DRAM, SRAM, and NAND FLASH devices.

Each of the lower core dies 300 may include a second semiconductor substrate 310, a second upper insulating layer 331, a second upper pad 332, a second penetration electrode 350, a second lower insulating layer 321, and a second lower pad 322.

The second semiconductor substrate 310 may be formed of or include at least one of semiconductor materials (e.g., silicon (Si)). The second penetration electrodes 350 may be provided to penetrate the second semiconductor substrate 310. The second penetration electrodes 350 may be spaced apart from each other in the first direction D1. The second penetration electrode 350 may be formed of or include at least one of conductive materials (e.g., copper). A diffusion prevention pattern (e.g., tantalum nitride (TaN), tantalum (Ta), titanium nitride (TiN), or tungsten (W)) may be disposed between the second penetration electrode 350 and the second semiconductor substrate 310.

The second lower insulating layer 321 may be disposed on a bottom surface of the second semiconductor substrate 310. Although not shown, an interconnection pattern and a circuit layer may be provided in the second lower insulating layer 321. The second lower pads 322 may be provided in the second lower insulating layer 321. Here, the second lower insulating layer 321 of a lower core die 300B, which is the lowermost one of the lower core dies 300, may be connected to the first upper insulating layer 131 of the base die 100 to form a hybrid bonding structure. In the present specification, the hybrid bonding structure may mean a bonding structure that is formed by two materials, which are of the same kind and are fused at an interface therebetween. The second lower pads 322 of the lower core die 300B, which is the lowermost one of the lower core dies 300, may be in contact with the first upper pads 132, respectively, of the base die 100.

The second upper insulating layer 331 may be disposed on a top surface of the second semiconductor substrate 310. The second upper pads 332 may be provided in the second upper insulating layer 331. The second lower insulating layer 321 and the second upper insulating layer 331 may be formed of or include at least one of silicon oxide (SiO₂), silicon nitride (Si₃N₄), and silicon oxynitride (SiOₓN_{y}).

The second upper insulating layer 331, which is included in one of the lower core dies 300, may be connected to the second lower insulating layer 321 of another lower core die 300 thereon. The second upper pads 332 in one of the lower core dies 300 may be in contact with the second lower pads 322 in another lower core die 300 thereon.

The upper core die 400 may be disposed on the lower core dies 300. The upper core die 400 may include a third semiconductor substrate 410, a third lower insulating layer 421, and a third lower pad 422. A thickness 400TH of the upper core die 400 may be larger than a thickness 300TH of each of the lower core dies 300.

The third semiconductor substrate 410 may be formed of or include at least one of semiconductor materials (e.g., silicon (Si)). Unlike the base die 100 and the lower core dies 300, the third semiconductor substrate 410 may not include penetration electrodes. A thickness of the third semiconductor substrate 410 in the third direction D3 may be larger than a thickness of the second semiconductor substrate 310 in the third direction D3. In an embodiment, the thickness of the third semiconductor substrate 410 in the third direction D3 may range from 50 μm to 300 μm.

The third lower insulating layer 421 may be disposed on a bottom surface of the third semiconductor substrate 410. The third lower pads 422 may be provided in the third lower insulating layer 421. Here, the second upper insulating layer 331 of a lower core die 300U, which is the uppermost one of the lower core dies 300, may be connected to the third lower insulating layer 421 of the upper core die 400 to form a hybrid bonding structure. The second upper pads 332 of the uppermost lower core die 300U may be in contact with the third lower pads 422 of the upper core die 400, respectively.

The oxide structure 450 may be disposed on the top surface of the base die 100. In detail, the oxide structure 450 may be provided to expose an edge portion of the top surface of the base die 100.

The oxide structure 450 may cover side surfaces of the lower core dies 300 and a side surface of the upper core die 400. That is, the oxide structure 450 may be provided to enclose opposite side surfaces of the lower core dies 300 and opposite side surfaces of the upper core die 400. A level of a top surface 400t of the upper core die 400 may be substantially equal to a level of a top surface 450t of the oxide structure 450. The expression “substantially equal to a level” may refer to being at the same level relative to the level compared therewith, and allows for approximations, inaccuracies, and limits of measurement under the relevant circumstances, appreciated by those of skill in the art. The expression “substantially equal to a level” may indicate that the levels compared therewith, which are intended to be the same, have some variation due to an unperfect process or a margin, an error, or a tolerance in manufacturing or measurement, recognized by those of skill in the art.

The oxide structure 450 may have a first width W1 in the first direction D1. The first width W1 may be constant regardless of a level. As an example, the first width W1 of the oxide structure 450 on the upper core die 400 may be substantially equal to the first width W1 of the oxide structure 450 on one of the lower core dies 300. The expression a value being “substantially equal to” another value may mean that the two values are the same, or the two values are almost the same but some variation due to an unperfect process or a margin, an error, or a tolerance in manufacturing or measurement, recognized by those of skill in the art. In one or more aspects, it may indicate an industry-accepted tolerance for the two values, such as a tolerance of ±1%, ±5%, or ±10% of the actual value stated, or other suitable tolerances. In an embodiment, the first width W1 may range from 20 μm to 50 μm. The oxide structure 450 may be formed of or include silicon oxide.

The molding structure 500 may be disposed on the base die 100. A bottom surface of the molding structure 500 may be in contact with the top surface of the base die 100. The molding structure 500 may be disposed on an outer side surface of the oxide structure 450 to cover a side surface of the oxide structure 450. The oxide structure 450 may be disposed between the upper core die 400 and the molding structure 500. That is, the molding structure 500 may be spaced apart from the lower and upper core dies 300 and 400 with the oxide structure 450 interposed therebetween. A level of the top surface 450t of the oxide structure 450 may be substantially equal to a level of a top surface 500t of the molding structure 500.

The molding structure 500 may have a second width W2 in the first direction D1. The second width W2 may be constant regardless of a level. The first width W1 of the oxide structure 450 may be larger than the second width W2 of the molding structure 500. In an embodiment, a ratio between the first width W1 and the second width W2 may range from 6:4 to 7:3.

The molding structure 500 may include an insulating material, and the insulating material may include an epoxy molding compound or an adhesive material.

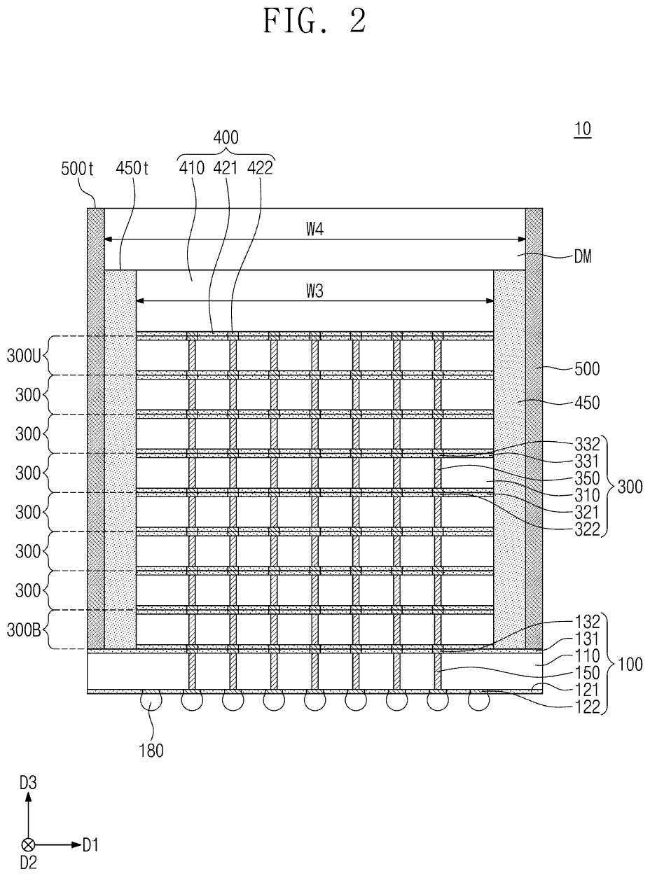

FIG. 2 is a sectional view illustrating a semiconductor package according to an embodiment of the inventive concept. For concise description, an element previously described with reference to FIG. 1 may be identified by the same reference number without repeating an overlapping description thereof.

Referring to FIG. 2, the semiconductor package 10 may further include a dummy plate DM. The dummy plate DM may be disposed on the upper core die 400. Here, the upper core die 400 may have a third width W3 in the first direction D1. The dummy plate DM may have a fourth width W4 in the first direction D1. The fourth width W4 may be larger than the third width W3.

A portion of a bottom surface of the dummy plate DM may be in contact with the oxide structure 450. Since the dummy plate DM is added, a level of the top surface 500t of the molding structure 500 may be higher than a level of the top surface 450t of the oxide structure 450. A side surface of the dummy plate DM may be aligned to the outer side surface of the oxide structure 450.

The dummy plate DM may be, for example, a silicon substrate. The dummy plate DM may not include devices (e.g., an integrated circuit), interconnection patterns, and penetration electrodes. In an embodiment, the dummy plate DM and the upper core die 400 may be connected to each other through a natural oxide layer.

In an embodiment, a semiconductor package may include lower core dies, an upper core die, and an oxide structure on a buffer die. Here, the oxide structure may be provided on a top surface of the buffer die to cover side surfaces of the lower and upper core dies. Thus, it may be possible to prevent the lower core dies and the upper core die from being deformed or bent and to prevent the lower core dies from being delaminated from the top surface of the buffer die. As a result, the structural stability of the semiconductor package may be improved.

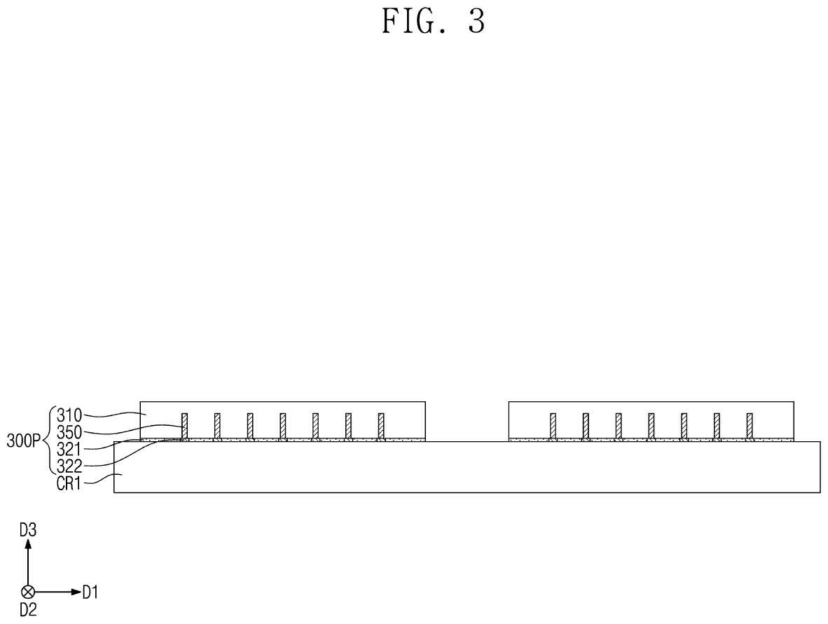

FIGS. 3, 4, 5, 6, 7, 8, 9, 10, 11, 12, 13, 14, 15, and 16 are sectional views illustrating a process of fabricating a semiconductor package, according to an embodiment of the inventive concept. In detail, FIGS. 3 to 16 are sectional views illustrating a process of fabricating the semiconductor package 10 of FIG. 1.

Referring to FIG. 3, a first carrier substrate CR1 may be provided. A plurality of preliminary lower core dies 300P may be provided on the first carrier substrate CR1. An adhesive member may be provided between the first carrier substrate CR1 and the preliminary lower core dies 300P. The preliminary lower core dies 300P may be spaced apart from each other in the first direction D1.

The preliminary lower core die 300P may include the second semiconductor substrate 310, the second penetration electrode 350, the second lower insulating layer 321, and the second lower pad 322. The second penetration electrode 350 may be provided to penetrate a portion of the second semiconductor substrate 310.

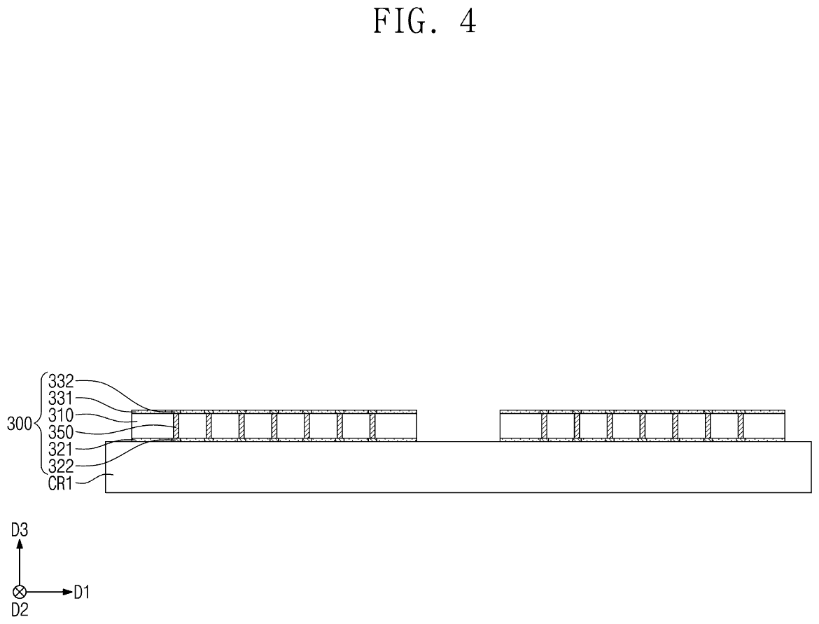

Referring to FIG. 4, a grinding process may be performed on the preliminary lower core dies 300P. The grinding process may be performed to expose a top surface of the second penetration electrode 350. As a result of the grinding process, a level of the top surface of the second semiconductor substrate 310 may be lowered.

Next, the second upper insulating layer 331 and the second upper pad 332 may be formed on the top surface of the second semiconductor substrate 310. Since the grinding process is performed and the second upper insulating layer 331 and the second upper pad 332 are formed, the lower core die 300 may be formed from the preliminary lower core die 300P.

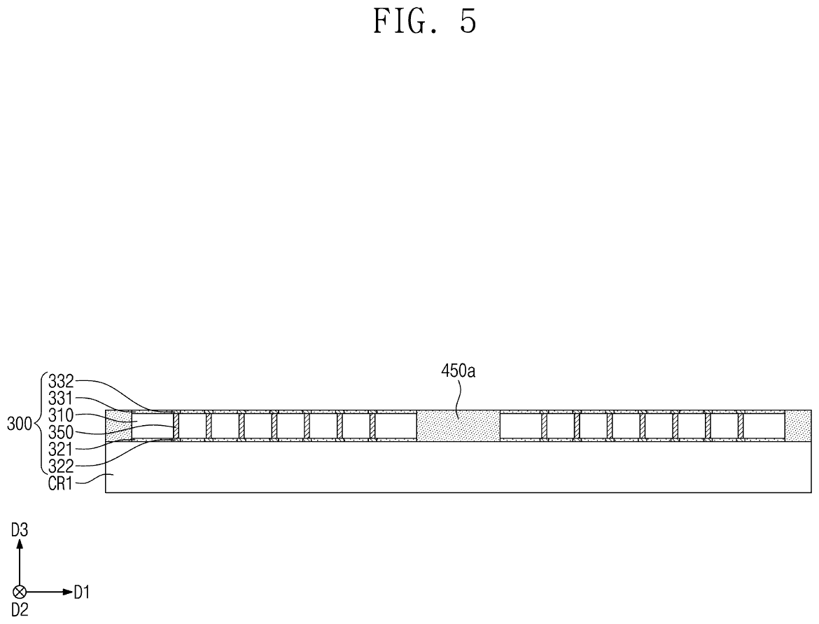

Referring to FIG. 5, a first oxide layer 450a may be formed on the first carrier substrate CR1. The formation of the first oxide layer 450a may include forming the first oxide layer 450a on the first carrier substrate CR1 to have a top surface that is placed at the same level as a top surface of the lower core die 300. The first oxide layer 450a may be provided to enclose a side surface of the lower core die 300. In an embodiment, the first oxide layer 450a may be formed through a chemical vapor deposition process.

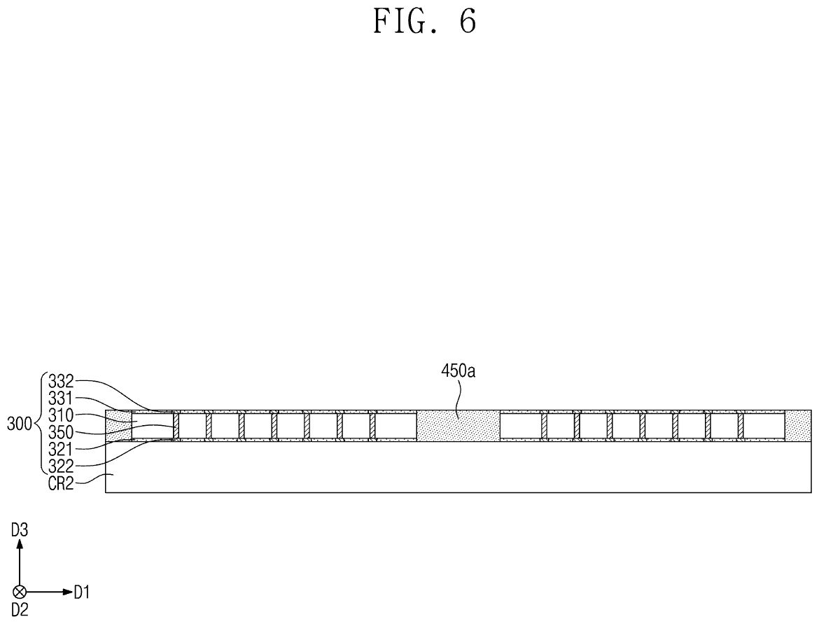

Referring to FIG. 6, another lower core die 300 and the first oxide layer 450a, which encloses a side surface of the lower core die 300, may be formed on a second carrier substrate CR2. The formation of the lower core die 300 and the first oxide layer 450a on the second carrier substrate CR2 may be performed through a process that is similar to the process described with reference to FIGS. 3 to 5.

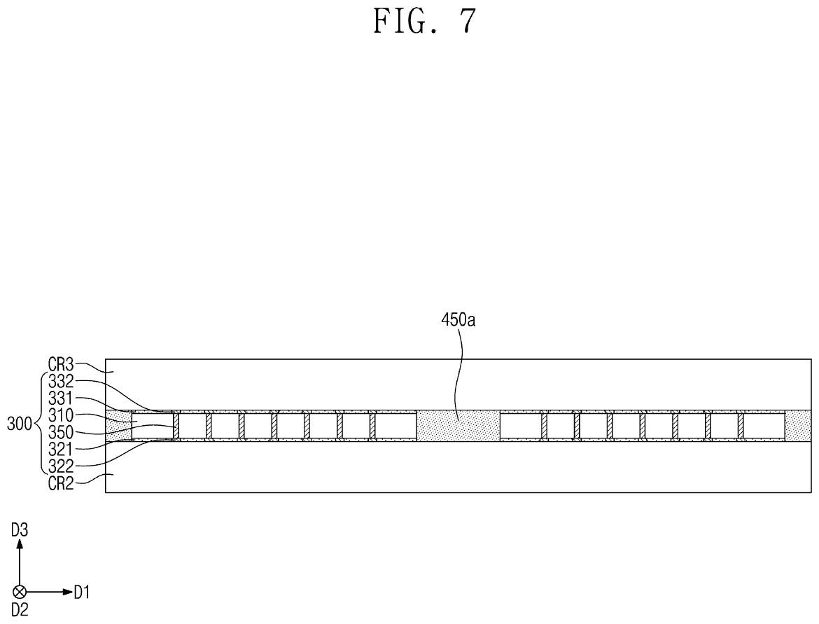

Referring to FIG. 7, a third carrier substrate CR3 may be provided. The third carrier substrate CR3 may be placed on and attached to the top surface of the lower core die 300 of FIG. 6. That is, the lower core die 300 may be placed between the second carrier substrate CR2 and the third carrier substrate CR3.

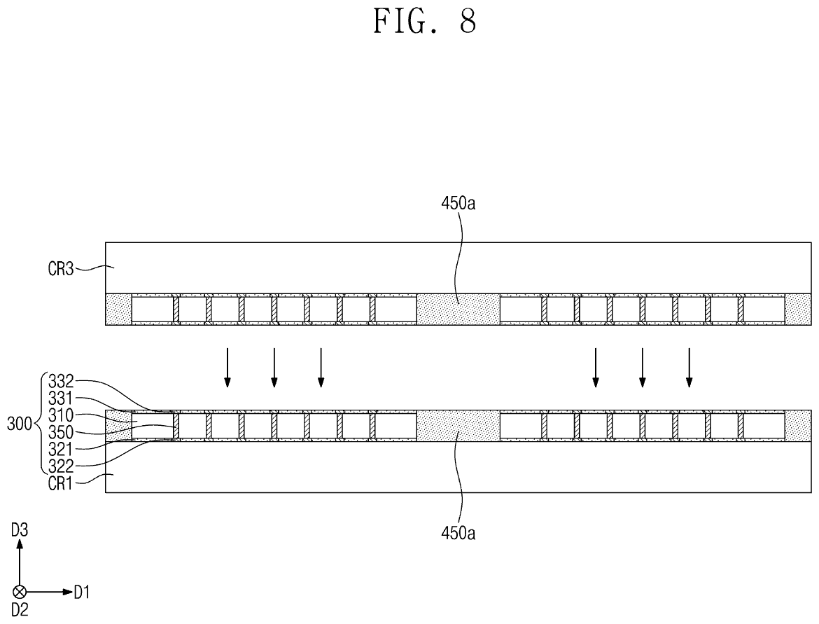

Referring to FIG. 8, the second carrier substrate CR2 may be removed. Thereafter, the lower core die 300 and the first oxide layer 450a on the third carrier substrate CR3 may be connected to the lower core die 300 and the first oxide layer 450a on the first carrier substrate CR1 of FIG. 5.

In detail, the second upper pads 332 in the lower core die 300 on the first carrier substrate CR1 may be in contact with the second lower pads 322 in the lower core die 300 on the third carrier substrate CR3, respectively.

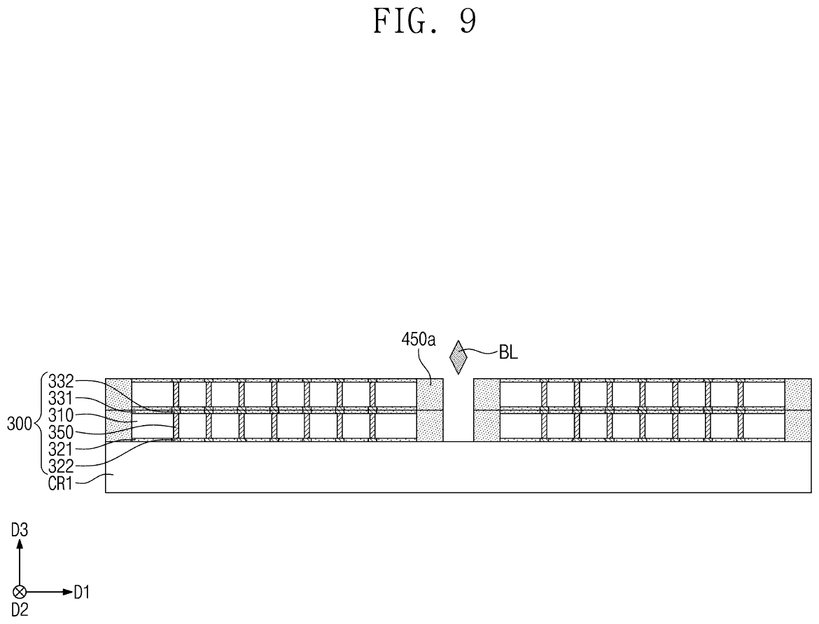

Referring to FIG. 9, the third carrier substrate CR3 may be removed. Next, a first sawing process may be performed on the first oxide layer 450a. As an example, the first sawing process may be performed using a sawing blade BL. As another example, the first sawing process may be performed using plasma.

As a result of the first sawing process, the first oxide layer 450a may be provided to form a plurality of portions, which are spaced apart from each other in the first direction D1. Each of the first oxide layers 450a may be provided to enclose a side surface of each of the lower core dies 300, which are spaced apart from each other in the first direction D1.

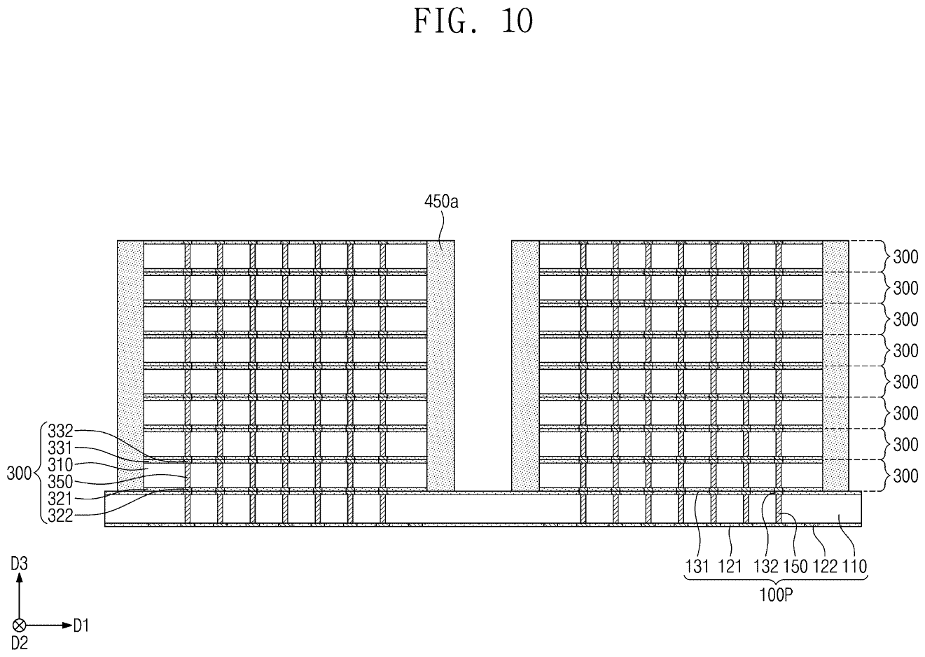

Referring to FIG. 10, a wafer 100P may be provided. The wafer 100P may include the first semiconductor substrate 110, the first upper insulating layer 131, the first upper pad 132, the first penetration electrode 150, the first lower insulating layer 121, and the first lower pad 122.

Next, the lower core dies 300 and the first oxide layer 450a, which are formed by the step of FIG. 9, may be detached from the first carrier substrate CR1 and may be stacked on the wafer 100P. Thereafter, the process of FIGS. 3 to 9 may be repeated.

As a result, the lower core dies 300, which are stacked in the third direction D3, and the first oxide layer 450a, which encloses side surfaces of the lower core dies 300, may be formed on the wafer 100P. The lower core dies 300 and the first oxide layer 450a may be provided to form a plurality of structures, which are provided on the wafer 100P and are spaced apart from each other in the first direction D1.

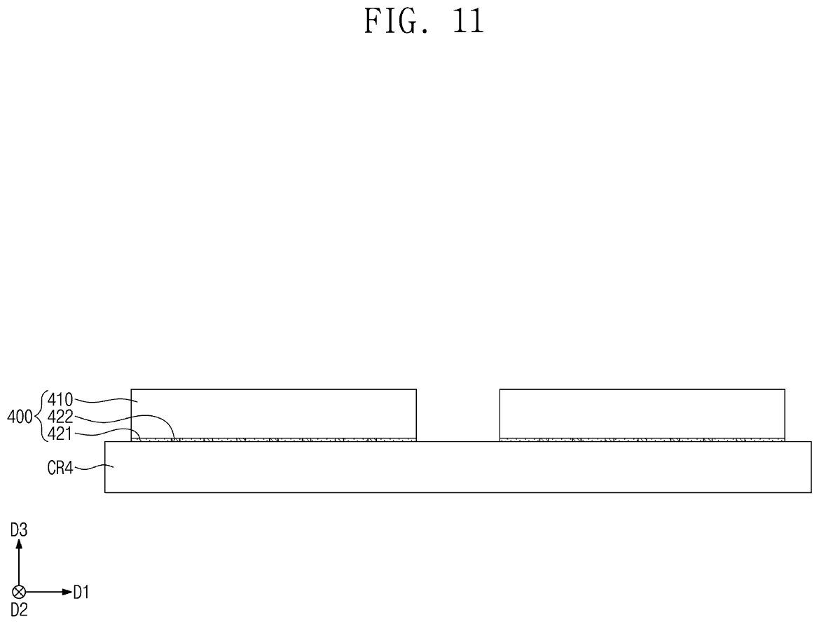

Referring to FIG. 11, a fourth carrier substrate CR4 may be provided. A plurality of upper core dies 400 may be provided on the fourth carrier substrate CR4. An adhesive member may be provided between the fourth carrier substrate CR4 and the upper core die 400. The upper core dies 400 may be spaced apart from each other in the first direction D1.

The upper core die 400 may include the third semiconductor substrate 410, the third lower insulating layer 421, and the third lower pad 422. Although not shown, a level of a top surface of the third semiconductor substrate 410 may be lowered through a grinding process.

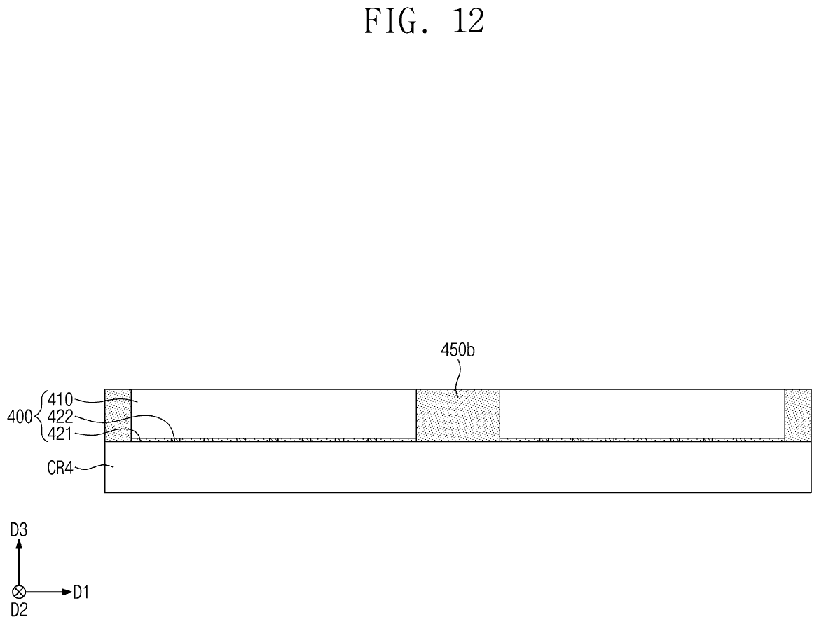

Referring to FIG. 12, a second oxide layer 450b may be formed on the fourth carrier substrate CR4. The formation of the second oxide layer 450b may include forming the second oxide layer 450b on the fourth carrier substrate CR4 to have a top surface that is placed at the same level as a top surface of the upper core die 400. The second oxide layer 450b may be formed to enclose the side surface of the upper core die 400. In an embodiment, the second oxide layer 450b may be formed through a chemical vapor deposition process.

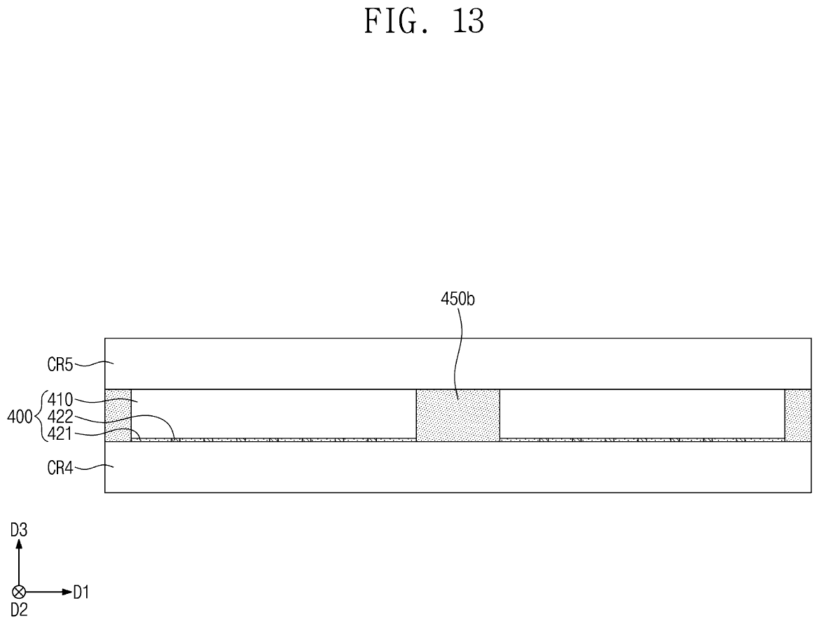

Referring to FIG. 13, a fifth carrier substrate CR5 may be provided. The fifth carrier substrate CR5 may be placed on and attached to the top surface of the upper core die 400 of FIG. 12. That is, the upper core die 400 may be placed between the fourth carrier substrate CR4 and the fifth carrier substrate CR5.

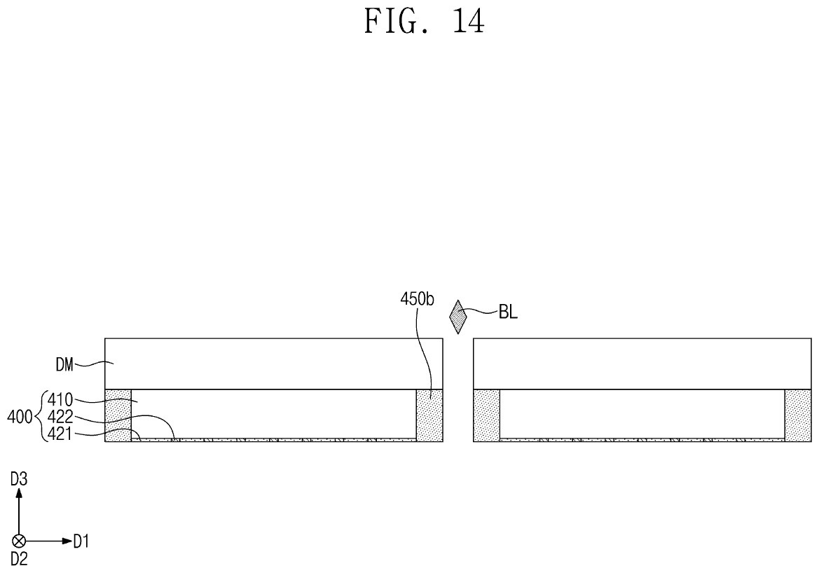

Referring to FIG. 14, the fourth carrier substrate CR4 may be removed. Next, a second sawing process may be performed on the fifth carrier substrate CR5 and the second oxide layer 450b. As an example, the second sawing process may be performed using the sawing blade BL. As another example, the second sawing process may be performed using plasma.

As a result of the second sawing process, the fifth carrier substrate CR5 may be divided to form the dummy plates DM, which are spaced apart from each other. As a result of the second sawing process, the second oxide layer 450b may be divided into a plurality of portions, which are spaced apart from each other in the first direction D1. Each of the second oxide layers 450b may be provided to enclose side surfaces of the upper core dies 400, which are spaced apart from each other in the first direction D1.

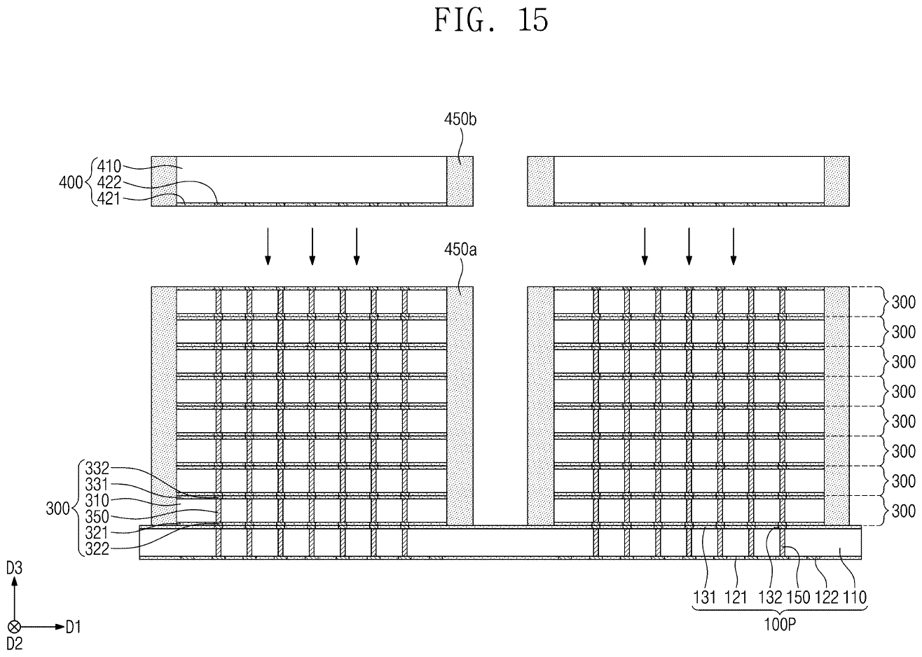

Referring to FIG. 15, the dummy plate DM may be removed. Thereafter, the upper core dies 400 and the second oxide layer 450b, which are formed by the step of FIG. 14, may be respectively stacked on the lower core dies 300 and the first oxide layers 450a of FIG. 10. In an embodiment, the stacking process may be performed through a thermal treatment process.

In detail, the stacking of the upper core die 400 on the lower core die 300 may include connecting the third lower pads 422 in the upper core die 400 to the second upper pads 332 in the uppermost lower core die 300U.

Since the first oxide layer 450a is connected to the second oxide layer 450b, the oxide structure 450 may be formed. The oxide structure 450 may be provided to enclose side surfaces of the lower core dies 300 and the upper core die 400.

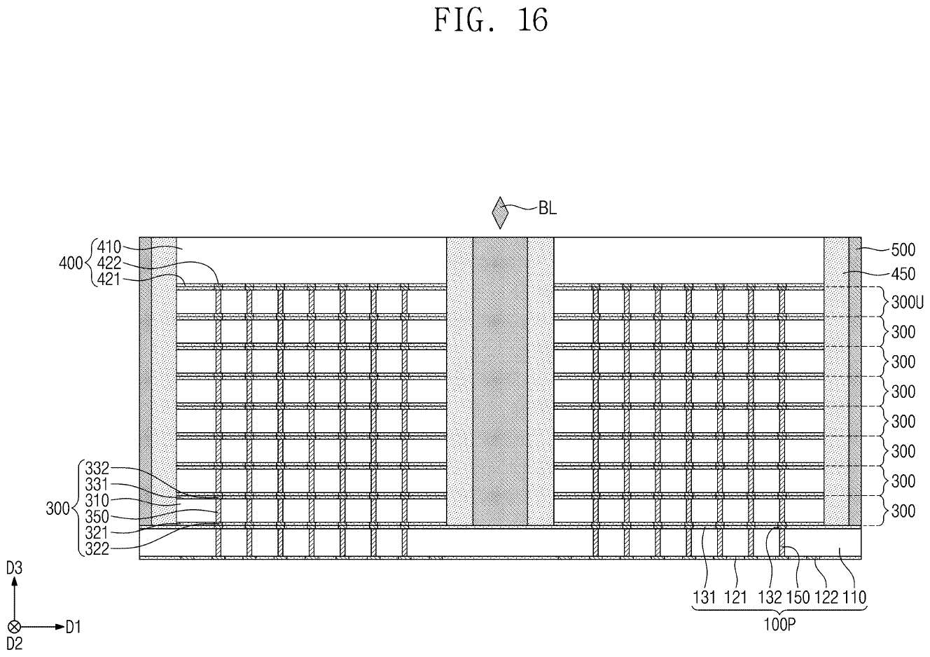

Referring to FIG. 16, the molding structure 500 may be formed on a top surface of the wafer 100P. The molding structure 500 may cover the side surface of the oxide structure 450. The formation of the molding structure 500 may include forming the molding structure 500 to have a top surface that is placed at the same level as a top surface of the oxide structure 450.

Next, a third sawing process may be performed on the wafer 100P and the molding structure 500. As an example, the third sawing process may be performed using the sawing blade BL. As another example, the third sawing process may be performed using plasma. As a result of the third sawing process, a plurality of base dies 100 (i.e., a plurality of buffer dies 100) may be formed from the wafer 100P.

Since the first connection terminals 180 are attached to the first lower pads 122 of the base die 100, a semiconductor package may be fabricated to have the structure of FIG. 1.

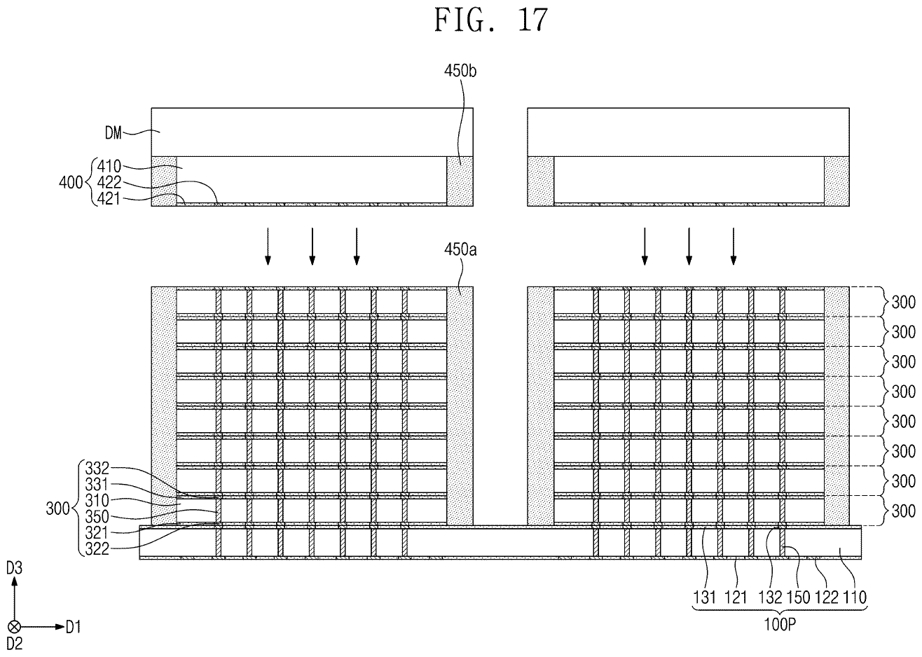

FIG. 17 is a sectional view illustrating a portion of a fabrication process of a semiconductor package according to an embodiment of the inventive concept. In detail, FIG. 17 is a sectional view illustrating a portion of a process of fabricating the semiconductor package of FIG. 2.

Referring to FIGS. 14 and 17, the dummy plate DM may not be removed from the upper core die 400. That is, the dummy plate DM and the upper core die 400 may be connected to each other. Next, the upper core die 400, which is connected to the dummy plate DM, may be placed on and connected to the lower core dies 300 of FIG. 10. Thereafter, a process, which is similar to the process described with reference to FIG. 16, may be performed to fabricate a semiconductor package according to an embodiment of the inventive concept.

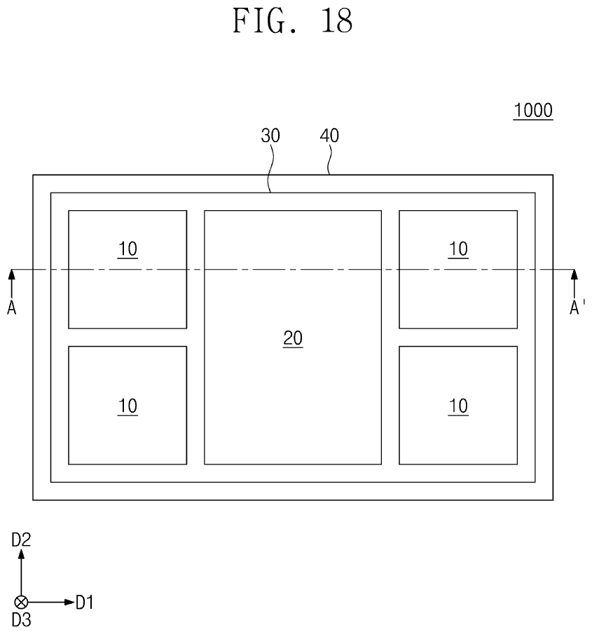

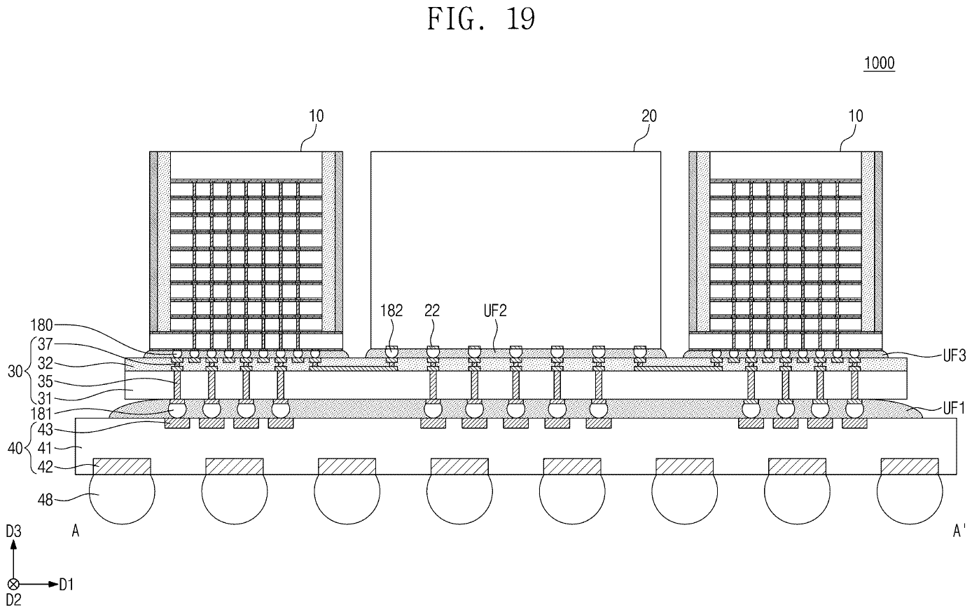

FIG. 18 is a plan view illustrating a semiconductor package according to an embodiment of the inventive concept. FIG. 19 is a sectional view taken along a line A-A′ of FIG. 18. For concise description, an element previously described with reference to FIG. 1 may be identified by the same reference number without repeating an overlapping description thereof.

Referring to FIGS. 18 and 19, a semiconductor package 1000 may include a package substrate 40, an interposer substrate 30, a logic chip 20, and a plurality of chip stacks 10. In an embodiment, the chip stack 10 of FIGS. 18 and 19 may correspond to the semiconductor packages 10 described with reference to FIG. 1.

The package substrate 40 may be, for example, a printed circuit board (PCB). Alternatively, the package substrate 40 may have a structure, in which insulating layers and interconnection layers are alternately stacked, although not shown. The package substrate 40 may include a plurality of upper substrate pads 43 on a top surface thereof and a plurality of lower substrate pads 42 on a bottom surface thereof.

Outer connection terminals 48 may be disposed on the lower substrate pads 42, respectively. The outer connection terminals 48 may be electrically connected to the interconnection layer and the upper substrate pads 43, which are provided in the package substrate 40, through the lower substrate pads 42.

The outer connection terminals 48 may include solder balls or solder bumps. The outer connection terminals 48 may be formed of or include at least one of silver, copper, tin, or alloys thereof.

The interposer substrate 30 may be disposed on the package substrate 40. The interposer substrate 30 may include an interposer core substrate 31, interposer vias 35, an interposer insulating layer 32, and interposer interconnection patterns 37.

The interposer core substrate 31 may be a semiconductor substrate (e.g., a silicon substrate). The interposer vias 35 may be provided to penetrate the interposer core substrate 31. The interposer vias 35 may be arranged in the first direction D1.

The interposer insulating layer 32 may be disposed on the interposer core substrate 31. The interposer insulating layer 32 may include the interposer interconnection patterns 37 provided therein. The interposer interconnection patterns 37 may be electrically connected to the interposer vias 35. The interposer insulating layer 32 may be formed of or include an insulating material (e.g., silicon oxide or silicon nitride). The interposer interconnection patterns 37 may be formed of or include a metallic material (e.g., copper).

Second connection terminals 181 and a first under-fill pattern UF1 may be disposed between the package substrate 40 and the interposer substrate 30. The first under-fill pattern UF1 may be provided to fill a space between the package substrate 40 and the interposer substrate 30 and to enclose a side surface of each of the second connection terminals 181. The second connection terminals 181 may be formed of or include a conductive material (e.g., a solder material). The first under-fill pattern UF1 may be formed of or include, for example, an epoxy resin.

The logic chip 20 and the chip stacks 10 may be disposed on the interposer substrate 30. In an embodiment, the logic chip 20 may be placed on a center portion of the interposer substrate 30. The chip stacks 10 may be spaced apart from each other in the first direction D1, with the logic chip 20 interposed therebetween. As shown in FIG. 18, a pair of the chip stacks 10 may be disposed to be adjacent to one side surface of the logic chip 20, and another pair of the chip stacks 10 may be disposed to be adjacent to an opposite side surface of the logic chip 20. Adjacent ones of the chip stacks 10 may be spaced apart from each other in the second direction D2. The arrangement of the logic chip 20 and the chip stacks 10 is not limited to the illustrated example and may be variously combined and modified.

The logic chip 20 may be one of a central processing unit (CPU), a graphics processing unit (GPU), and an application specific integrated circuit (ASIC). The logic chip 20 may be configured to transmit signals to the chip stack 10 or to receive signals from the chip stack 10. The logic chip 20 may include chip pads 22 provided in a lower portion thereof. Third connection terminals 182 may be disposed on the chip pads 22, respectively. The third connection terminals 182 may be formed of or include a conductive material (e.g., a solder material).

The first connection terminals 180 of the chip stack 10 and the third connection terminals 182 of the logic chip 20 may be in contact with pads on a top surface of the interposer substrate 30. A second under-fill pattern UF2 may be disposed between the logic chip 20 and the interposer substrate 30. The second under-fill pattern UF2 may be provided to fill a space between the third connection terminals 182. A third under-fill pattern UF3 may be interposed between the chip stack 10 and the interposer substrate 30. The third under-fill pattern UF3 may be provided to fill a space between the first connection terminals 180. The second and third under-fill patterns UF2 and UF3 may be formed of or include at least one of epoxy resin or resin compounds.

According to an embodiment of the inventive concept, a semiconductor package may include lower core dies, an upper core die, and an oxide structure on a buffer die. Here, the oxide structure may be provided to enclose side surfaces of the lower and upper core dies. Thus, it may be possible to prevent the lower core dies and the upper core die from being deformed or bent and to prevent the lower core dies from being delaminated from the top surface of the buffer die. As a result, the structural stability of the semiconductor package may be improved.

While example embodiments of the inventive concept have been particularly shown and described, it will be understood by one of ordinary skill in the art that variations in form and detail may be made therein without departing from the spirit and scope of the attached claims.

What is claimed is:

1. A semiconductor package, comprising:
a base die;
a plurality of lower core dies stacked on the base die;
an upper core die on the plurality of lower core dies;
an oxide structure covering side surfaces of the plurality of lower core dies and a side surface of the upper core die; and
a molding structure provided to cover a side surface of the oxide structure and spaced apart from the plurality of lower core dies and the upper core die with the oxide structure interposed therebetween,
wherein each of the base die and the plurality of lower core dies comprises a penetration electrode,
the upper core die comprises an insulating layer provided on a bottom surface thereof and a pad provided in the insulating layer, and
the oxide structure exposes an edge portion of a top surface of the base die.

2. The semiconductor package of claim 1, wherein the oxide structure comprises silicon oxide.

3. The semiconductor package of claim 1, wherein a top surface of the oxide structure is located at substantially the same level as a top surface of the molding structure.

4. The semiconductor package of claim 1, wherein a width of the oxide structure in a first direction parallel to a top surface of the base die is constant regardless of a level.

5. The semiconductor package of claim 1, wherein the oxide structure has a first width in the first direction,
the molding structure has a second width in the first direction, and
the first width is larger than the second width.

6. The semiconductor package of claim 5, wherein a ratio of the first width to the second width ranges from 6:4 to 7:3.

7. The semiconductor package of claim 5, wherein the first width ranges from 20 μm to 50 μm.

8. The semiconductor package of claim 1, wherein the upper core die does not include a penetration electrode.

9. A semiconductor package, comprising:
a base die;
a plurality of lower core dies stacked on the base die;
an upper core die on the plurality of lower core dies;
an oxide structure covering side surfaces of the plurality of lower core dies and a side surface of the upper core die; and
a molding structure on a side surface of the oxide structure,
wherein a width of the oxide structure in a horizontal direction is constant regardless of a level, and
a level of a top surface of the upper core die is substantially equal to a level of a top surface of the oxide structure.

10. The semiconductor package of claim 9, wherein a width of the molding structure in the horizontal direction is constant regardless of a level.

11. The semiconductor package of claim 9, further comprising a dummy plate on the upper core die,
wherein the dummy plate has a first width in the horizontal direction,
the upper core die has a second width in the horizontal direction, and
the first width is larger than the second width.

12. The semiconductor package of claim 11, wherein a level of a top surface of the molding structure is higher than the level of the top surface of the oxide structure.

13. The semiconductor package of claim 11, wherein a side surface of the dummy plate is aligned to an outer side surface of the oxide structure.

14. The semiconductor package of claim 11, wherein the upper core die further comprises an insulating layer on a bottom surface thereof and a pad provided in the insulating layer, and
the upper core die and the dummy plate are free of a penetration electrode.

15. A semiconductor package, comprising:
a package substrate;
an interposer substrate on the package substrate;
a logic chip on the interposer substrate; and
a plurality of chip stacks, which are spaced apart from each other in a first direction parallel to a top surface of the package substrate, with the logic chip interposed therebetween,
wherein one of the plurality of chip stacks comprises:
a base die;
a plurality of lower core dies stacked on the base die;
an upper core die on the plurality of lower core dies;
an oxide structure covering side surfaces of the plurality of lower core dies and a side surface of the upper core die; and
a molding structure covering a side surface of the oxide structure,
wherein a width of the oxide structure on the upper core die in the first direction is substantially equal to a width of the oxide structure on one of the plurality of lower core dies in the first direction.

16. The semiconductor package of claim 15, wherein the oxide structure is disposed between the upper core die and the molding structure.

17. The semiconductor package of claim 15, wherein a thickness of the upper core die is larger than a thickness of each of the plurality of lower core dies.

18. The semiconductor package of claim 15, wherein a bottom surface of the molding structure is in contact with a top surface of the base die.

19. The semiconductor package of claim 15, wherein each of the base die and the plurality of lower core dies comprises a penetration electrode, and
the upper core die does not include a penetration electrode.

20. The semiconductor package of claim 15, wherein each of the plurality of lower core dies comprises a first insulating layer on a top surface thereof and a first pad provided in the first insulating layer,
the upper core die comprises a second insulating layer on a bottom surface thereof and a second pad provided in the second insulating layer, and
the first pad of an uppermost one of the plurality of lower core dies is in contact with the second pad of the upper core die.
